(19) United States
(12) Patent Application Publication
(10) Pub. No.: US 2025/0072049 A1
(43) Pub. Date: Feb. 27, 2025

(54) SEMICONDUCTOR DEVICE ISOLATION OF CONTACT AND SOURCE/DRAIN STRUCTURES

(71) Applicant: Taiwan Semiconductor Manufacturing Company, Ltd., Hsinchu (TW)

(72) Inventors: Szu-Chien WU, Hsinchu County (TW); Chun-Yuan CHEN, HsinChu (TW); Huan-Chieh SU, Changhua County (TW); Kuo-Cheng CHIANG, Hsinchu County (TW); Chih-Hao WANG, Hsinchu (TW)

(73) Assignee: Taiwan Semiconductor Manufacturing Company, Ltd., Hsinchu (TW)

(21) Appl. No.: 18/945,264

(22) Filed: Nov. 12, 2024

Related U.S. Application Data
(63) Continuation-in-part of application No. 18/489,367, filed on Oct. 18, 2023.
(60) Provisional application No. 63/510,159, filed on Jun. 26, 2023.

(51) Int. Cl. H01L 29/417; H01L 21/285; H01L 29/06; H01L 29/423; H01L 29/45; H01L 29/66; H01L 29/775; H01L 29/786

(52) U.S. Cl. CPC H01L 29/41733; H01L 21/28518; H01L 29/0673; H01L 29/42392; H01L 29/45; H01L 29/66439; H01L 29/775; H01L 29/78696

(57) ABSTRACT

The present disclosure describes a semiconductor device having a dielectric structure between a source/drain (S/D) structure and a contact structure. The semiconductor device includes a S/D structure on a substrate, a dielectric structure on a top surface of the S/D structure, and a S/D contact structure on the S/D structure and the dielectric structure. A portion of the S/D contact structure is in contact with a top surface of the dielectric structure.

### CROSS-REFERENCE TO RELATED APPLICATION

This application is a continuation-in-part of U.S. patent application Ser. No. 18/489,367, titled “Semiconductor Device Isolation of Contact and Source/Drain Structures,” filed on Oct. 18, 2023, which claims the benefit of U.S. Provisional Patent Application No. 63/510, 159, titled “A MD/EPI Isolation Approach Formed with MD Spacer,” filed Jun. 26, 2023, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1A illustrates an isometric view of a first portion of a semiconductor device having a contact structure isolated from a source/drain structure, in accordance with some embodiments.

FIG. 1B illustrates an isometric view of a second portion of a semiconductor device having a dielectric structure between a source/drain structure and a contact structure, in accordance with some embodiments.

FIGS. 2A and 2B illustrate cross-sectional views of a first portion of a semiconductor device having a contact structure isolated from a source/drain structure, in accordance with some embodiments.

FIGS. 2C and 2D illustrate cross-sectional views of a second portion of a semiconductor device having a dielectric structure between a source/drain structure and a contact structure, in accordance with some embodiments.

FIG. 3 illustrates a layout of a first portion of a semiconductor device having a contact structure isolated from a source/drain structure, in accordance with some embodiments.

FIG. 4 illustrates an isometric view of interconnect connections of a first portion of a semiconductor device having a contact structure isolated from a source/drain structure, in accordance with some embodiments.

FIG. 5 is a flow diagram of a method for fabricating a first portion of a semiconductor device having a contact structure isolated from a source/drain structure, in accordance with some embodiments.

FIGS. 6-18 illustrate isometric and cross-sectional views of a first portion of a semiconductor device having a contact structure isolated from a source/drain structure at various stages of its fabrication, in accordance with some embodiments.

FIG. 19 is a flow diagram of a method for fabricating a second portion of a semiconductor device having a dielectric structure between a source/drain structure and a contact structure, in accordance with some embodiments.

FIGS. 20-27B illustrate isometric and cross-sectional views of a second portion of a semiconductor device having a dielectric structure between a source/drain structure and a contact structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a first source/drain (S/D) structure of a first nanostructure transistor can be electrically connected to a second S/D structure of a second nanostructure transistor at different sides of a gate structure through contact structures, via structures, first level metal lines (M0), first level metal vias (V0), and second level metal lines (M1). However, these metal lines and metal vias can require a larger cell height and more metal interconnects, which consume a larger chip area for a semiconductor device. Additionally, contact structures of a third nanostructure transistor may get closer to S/D structures of an adjacent fourth nanostructure transistor due to an overlay shift. The decrease of the distance between the contact structures and adjacent S/D structures may cause time-dependent dielectric breakdown (TDDB) and reduce the reliability of the semiconductor device.

Some embodiments of the present disclosure provide methods for forming a contact structure isolated from a S/D structure in a first portion of a semiconductor device and/or other semiconductor devices in an integrated circuit (IC). In some embodiments, first and second transistors can be formed on a substrate. The first transistor can includes first and second S/D structures and the second transistor can include a third S/D structure adjacent to the second S/D structure. An isolation layer can be formed on the second S/D structure. A S/D contact structure can be formed over the second and third S/D structures. The third S/D structure can be electrically connected to the S/D contact structure. The isolation layer can isolate the second S/D structure from the S/D contact structure. In this way, the first and third S/D structures can be electrically connected through the S/D contact structure, metal lines M0, and metal vias V0 without additional interconnects, such as metal lines M1. As a result, the cell height of the semiconductor device can be reduced with fewer metal interconnects and the chip area of the semiconductor device can be reduced by about 2% to about 6%.

Some embodiments of the present disclosure provide methods for forming a dielectric structure between a S/D structure and a contact structure in a second portion of a semiconductor device and/or other semiconductor devices in an IC. In some embodiments, a S/D structure can be formed on a substrate. A dielectric structure can be formed on a top surface of the S/D structure. A S/D contact structure can be formed on the S/D structure and the dielectric structure. A portion of the S/D contact structure can be in contact with a top surface of the dielectric structure. With the dielectric structure between the S/D structure and the portion of the S/D contact structure, a distance between the S/D contact structures and adjacent S/D structures can be increased. As a result, TDDB can be reduced and the reliability of the semiconductor device can be improved.

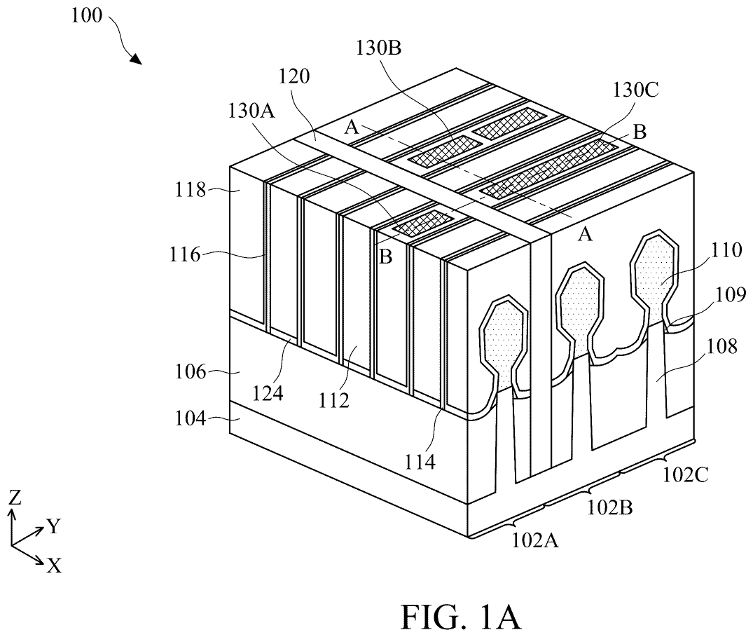

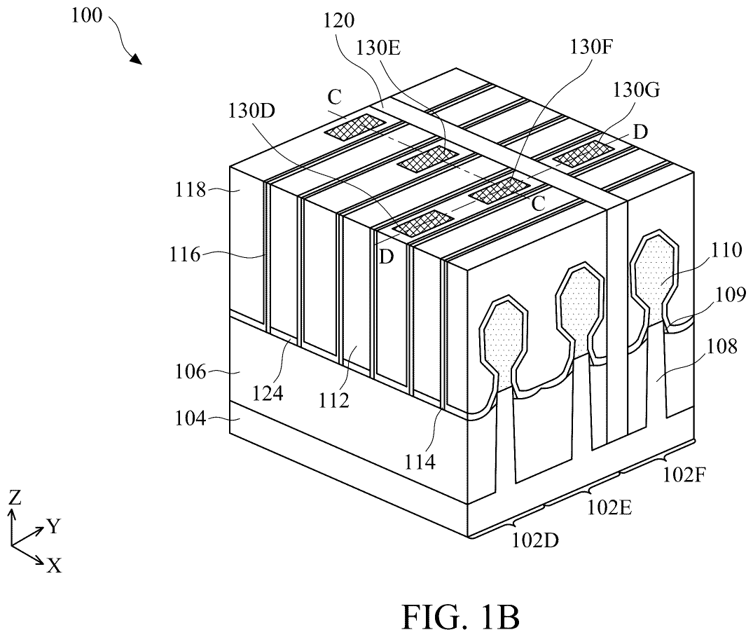

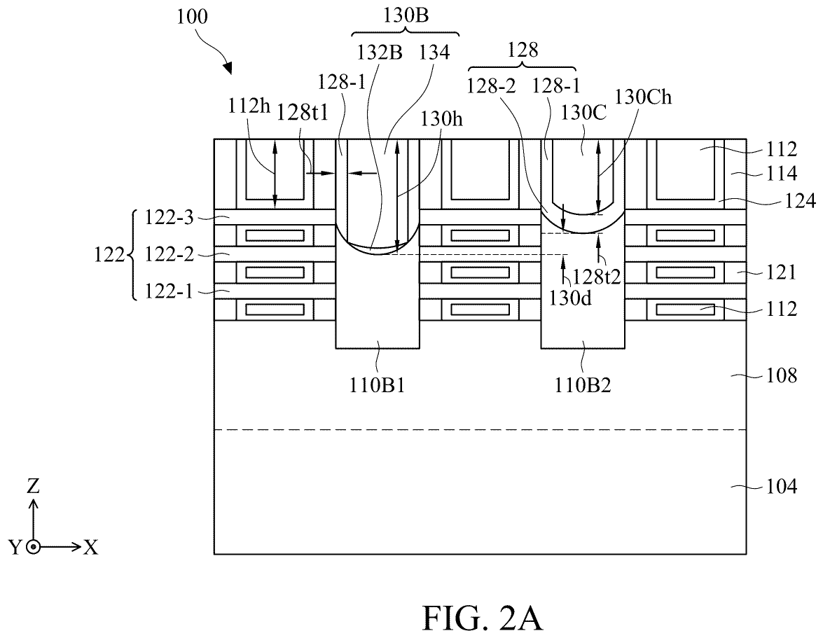

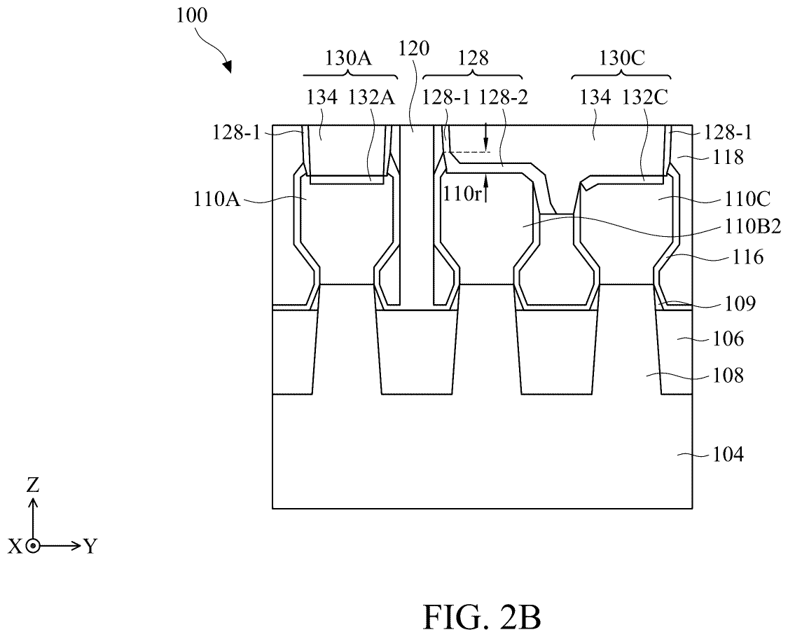

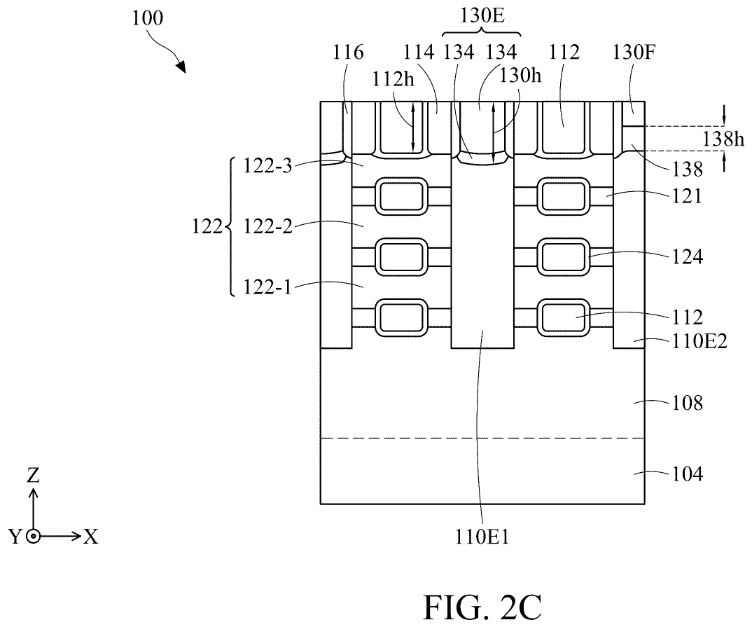

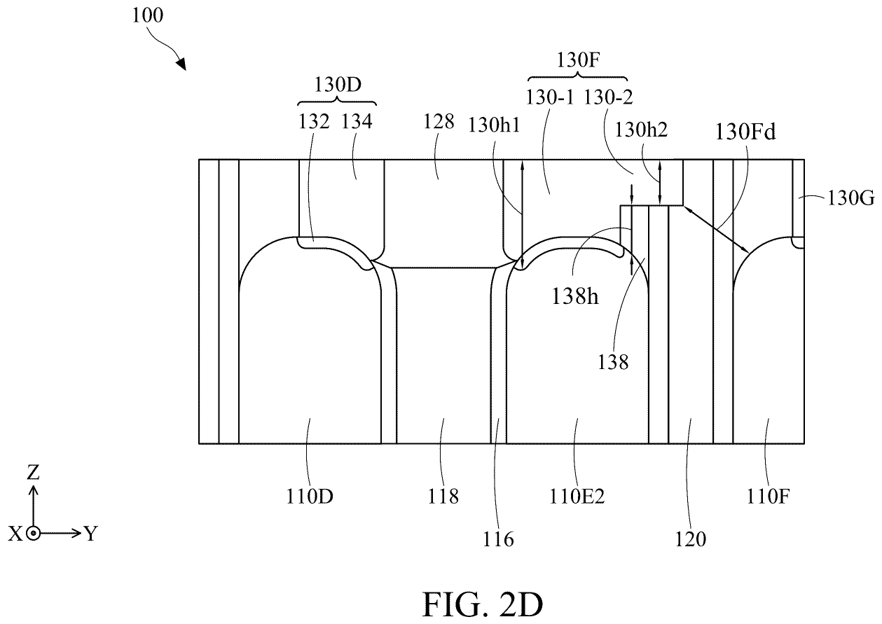

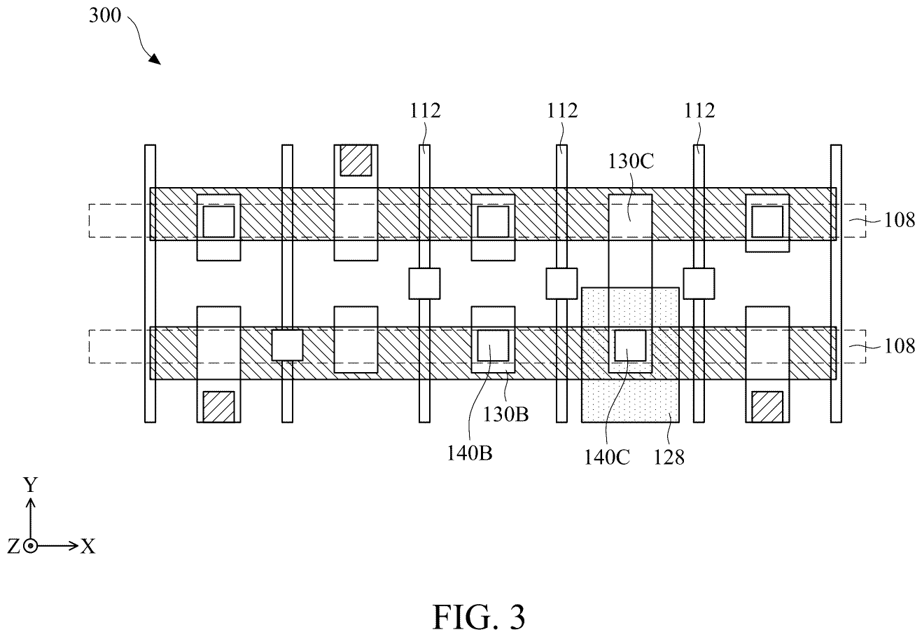

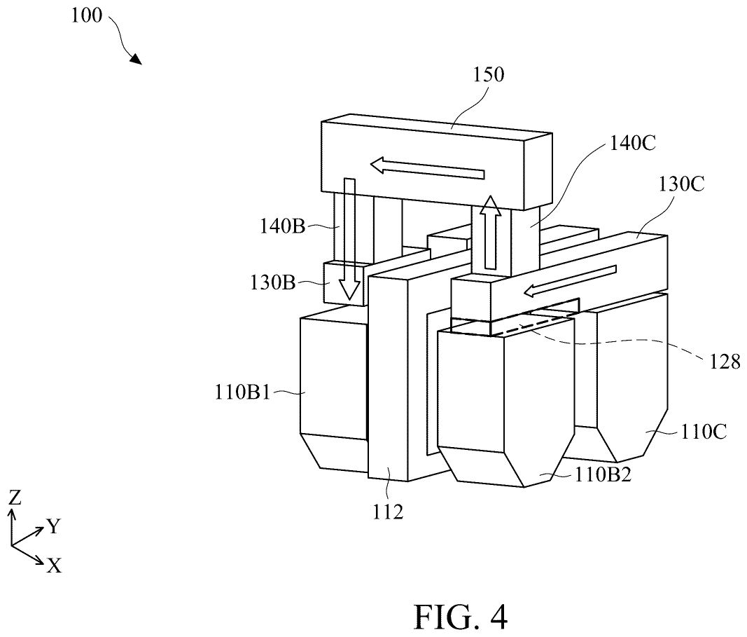

FIG. 1A illustrates an isometric view of a first portion of a semiconductor device 100 having a contact structure isolated from a S/D structure, in accordance with some embodiments. FIGS. 2A and 2B illustrate cross-sectional views of the first portion of semiconductor device 100 across line A-A and line B-B shown in FIG. 1A, respectively, in accordance with some embodiments. FIG. 1B illustrates an isometric view of a second portion of semiconductor device 100 having a dielectric structure between a S/D structure and a contact structure, in accordance with some embodiments. FIGS. 2C and 2D illustrate cross-sectional views of the second portion of semiconductor device 100 across line C-C and line D-D shown in FIG. 1B, respectively, in accordance with some embodiments. FIG. 3 illustrates a layout 300 of semiconductor device 100 having a contact structure isolated from a S/D structure, in accordance with some embodiments. FIG. 4 illustrates an isometric view of interconnect connections of semiconductor device 100 having a contact structure isolated from a S/D structure, in accordance with some embodiments. In some embodiments, the first portion of semiconductor device 100 can include transistors 102A-102C and the second portion of semiconductor device 100 can include transistors 102D-102F, as shown in FIGS. 1A and 1B, respectively. In some embodiments, transistors 102A-102F can include nanostructure transistors. The nanostructure transistors can include finFETs, gate-all-around field effect transistors (GAA FETs), nanosheet transistors, nanowire transistors, multi-bridge channel transistors, nano-ribbon transistors, and other similar structured transistors. The nanostructure transistors can provide a channel in a stacked nanosheet/nanowire configuration.

In some embodiments, transistors 102A-102F can be n-type field-effect transistors (NFETs). In some embodiments, transistors 102A-102F can be p-type field-effect transistors (PFETs). In some embodiments, any of transistors 102A-102F can be an NFET or a PFET. In some embodiments, transistors 102D and 102E can be in a cell. In some embodiments, a cell height of transistors 102D and 102E, e.g., a distance of transistors 102D and 102E along a Y-axis, can range from about 70 nm to about 160 nm. Though each of FIGS. 1A and 1B shows three transistors, first and second portions of semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102F with the same annotations applies to each other, unless mentioned otherwise. And like reference numerals generally indicate identical, functionally similar, and/or structurally similar elements.

Referring to FIGS. 1A-4, semiconductor device 100 having transistors 102A-102F can be formed on a substrate 104 and can be isolated by shallow trench isolation (STI) regions 106. Each of transistors 102A-102F can include fin structures 108 (a protrusion/base structure extended from substrate 104), sidewall spacers 109, gate dielectric layer 124, gate structures 112, gate spacers 114, S/D structures 110A, 110B1, 110B2, 110C, 110D, 110E1, 110E2, and 110F (collectively referred to as “S/D structures 110”), etch stop layer (ESL) 116, and interlayer dielectric (ILD) layer 118. In some embodiments, as shown in FIGS. 2A and 2C, transistors 102A-102F can have nanostructures 122-1, 122-2, and 122-3 (collectively referred to as “nanostructures 122”) on fin structures 108.

Referring to FIGS. 1A-1B and 2A-2D, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102F and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1A-1B and 2A-2D, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1A-1B, 2A, and 2C, nanostructures 122 and fin structures 108 can extend along an X-axis for transistors 102A-102F. In some embodiments, nanostructures 122 and fin structures 108 can be disposed on substrate 104. Nanostructures 122 can include a set of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102F. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2A and 2C, nanostructures 122 under gate structures 112 can form channel regions of semiconductor device 100 and represent current carrying channel structures of semiconductor device 100. Though three layers of nanostructures 122 are shown in FIGS. 2A and 2C, transistors 102A-102F can have any number of nanostructures 122. In some embodiments, transistors 102A-102F can have two to six layers of nanostructures 122.

In some embodiments, nanostructures 122 can have a thickness along a Z-axis ranging from about 5 nm to about 8 nm. In some embodiments, nanostructures 122 can have a width along a Y-axis ranging from about 15 nm to about 50 nm. In some embodiments, a spacing between adjacent nanostructures 122 along a Z-axis can range from about 8 nm to about 12 nm.

Referring to FIGS. 1A-1B, 2A, and 2C, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1A-1B, 2A, and 2C, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102F. In some embodiments, gate structures 112 for NFET and PFET devices can have the same work-function metal. In some embodiments, gate structures 112 for NFET and PFET devices can have different work-function metals. In some embodiments, as shown in FIGS. 2A and 2C, each of nanostructures 122 can be wrapped around by gate structures 112, for which gate structures 112 can be referred to as “gate-all-around (GAA) structures” and transistors 102A-102F can also be referred to as “GAA FETs 102A-102F.” The one or more work function metal layers can wrap around nanostructures 122 and can include work function metals to tune the Vₜ of transistors 102A-102F. In some embodiments, transistors 102A-102F can include any number of work function metal layers for Vₜ tuning (e.g., ultra-low Vₜ, low Vₜ, and standard Vₜ). In some embodiments, as shown in FIGS. 2A and 2C, gate structures 112 can have a height 112h above nanostructures 122 along a Z-axis ranging from about 10 nm to about 35 nm.

In some embodiments, NFETs 102A-102F can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102F can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1A-1B and 2A-2D, gate spacers 114 can be disposed on sidewalls of gate structures 112, and sidewall spacers 109 can be disposed on sidewalls of fin structures 108. Gate spacers 114 and sidewall spacers 109 can include insulating materials, such as silicon oxide, silicon nitride, silicon oxynitride, silicon carbonitride, silicon oxycarbide, silicon oxycarbonitride, a low-k material, and a combination thereof. Gate spacers 114 and sidewall spacers 109 can include a single layer or a stack of insulating layers. Gate spacers 114 and sidewall spacers 109 can have a low-k material with a dielectric constant less than about 3.9 (e.g., about 3.5, about 3.0, or about 2.8).

S/D structures 110 can be disposed on fin structures 108 and on opposing sides of gate structures 112. S/D structures 110 can function as S/D regions of transistors 102A-102F. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structure 110 can have a height along a Z-axis ranging from about 9 nm to about 60 nm. In some embodiments, as shown in FIG. 2B, S/D structures 110 can have a recess 110r for deposition of dielectric layer 128 and formation of S/D contact structures 130. Recess 110r can range from a top end of ESL 116 to an interface between S/D structures 110 and dielectric layer 128, as shown in FIG. 2B. In some embodiments, recess 110r can range from about 2 nm to about 10 nm.

ESL 116 can be disposed on STI regions 106, S/D structures 110, and sidewalls of gate spacers 114 and sidewall spacers 109. ESL 116 can be configured to protect STI regions 106, S/D structures 110, and gate structures 112 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1A-4, semiconductor device 100 can further include gate isolation structure 120, S/D contact structures 130A, 130B, 130C, 130D, 130E, 130F, and 130G (collectively referred to as “S/D contact structures 130”), first portion 128-1 and second portion 128-2 of dielectric layer 128 (collectively referred to as “dielectric layer 128”), dielectric structure 138, metal vias 140B and 140C (collectively referred to as “metal vias 140”), and metal line 150.

Referring to FIGS. 1A-1B, 2B, and 2D, gate isolation structure 120 can be disposed on substrate 104 and electrically isolate transistor 102A from transistors 102B and 102C as well as transistor 102F from transistors 102D and 102E. In some embodiments, as shown in FIGS. 1A-1B, gate isolation structure 120 can extend through gate structures 112 and separate gate structures 112 into two portions. In some embodiments, gate isolation structure 120 can include silicon nitride, silicon oxide, and/or other suitable dielectric materials. In some embodiments, gate isolation structure 120 can include a single dielectric layer or a stack of dielectric layers. In some embodiments, gate isolation structure 120 can extend vertically through gate structures 112. In some embodiments, gate isolation structure 120 can extend through STI regions 106.

In some embodiments, as shown in FIGS. 1A, 2A, and 2B, S/D contact structures 130A, 130B, and 130C can be disposed on S/D structures 110A, 110B1, 110B2, and 110C. In some embodiments, S/D contact structures 130A, 130B, and 130C can include silicide layers 132A, 132B, and 132C (collectively referred to as “silicide layers 132”) and metal contact 134. In some embodiments, as shown in FIGS. 1B, 2C, and 2D, S/D contact structures 130D, 130E, and 130F can be disposed on S/D structures 110D, 110E1, 110E2, and 110F. In some embodiments, S/D contact structures 130D, 130E, and 130F can also include silicide layers 132 and metal contact 134. In some embodiments, silicide layers 132 can include metal silicide and can provide a lower resistance interface between metal contact 134 and S/D structures 110. Examples of metal used for forming the metal silicide include cobalt, titanium, and nickel. In some embodiments, metal contact 134 can include conductive materials, such as tungsten, aluminum, and cobalt. In some embodiments, as shown in FIGS. 2A-2D, S/D contact structures 130 can have a height 130h along a Z-axis above S/D structures 110 ranging from about 8 nm to about 40 nm. In some embodiments, height 130h of S/D contact structures can be equal or greater than height 112h of gate structures 112.

In some embodiments, as shown in FIGS. 2A-2B, a portion of S/D contact structure 130C can be on dielectric layer 128. In some embodiments, the portion of S/D contact structure 130C can be referred to as a “S/D contact flyer.” In some embodiments, the portion of S/D contact structure 130C on dielectric layer 128 can have a height 130Ch along a Z-axis ranging from about 6 nm to about 22 nm. In some embodiments, a depth difference 130d along a Z-axis between bottom surfaces of S/D contact structure 130B and second portion 128-2 of dielectric layer 128 can range from about 2 nm to about 10 nm.

In some embodiments, as shown in FIGS. 2A-2B, 3, and 4, dielectric layer 128 can be disposed on sidewalls of S/D contact structures 130 and between S/D contact structure 130C and S/D structure 110B2. In some embodiments, dielectric layer 128 can include a dielectric material, such as silicon nitride, silicon oxycarbide, silicon carbonitride, silicon oxynitride, silicon oxynitricarbide, and a combination thereof. In some embodiments, dielectric layer 128 can include silicon nitride and ILD 118 can include silicon oxide. As shown in FIGS. 2A and 2B, dielectric layer 128 can include first portion 128-1 on sidewalls of S/D contact structures 130 and second portion 128-2 between S/D contact structure 130C and S/D structure 110B2. In some embodiments, first portion 128-1 of dielectric layer 128 on sidewalls of S/D contact structures 130 can act as S/D contact spacers and can be referred to as “S/D contact spacers 128-1.” In some embodiments, S/D contact spacers 128-1 can be uniform and can have a thickness 128tl ranging from about 2 nm to about 5 nm. In some embodiments, S/D contact spacers 128-1 can be in contact with ILD layer 118. In some embodiments, second portion 128-2 of dielectric layer 128 between S/D contact structure 130C and S/D structures 110B2 can act an isolation layer and can be referred to as “S/D isolation layer 128-2.” In some embodiments, S/D isolation layer 128-2 can be conformal on S/D structure 110B2 and can have a thickness 128t2 ranging from about 2 nm to about 8 nm. In some embodiments, a ratio of height 130Ch to thickness 128t2 can range from about 3 to about 10. If the ratio is greater than about 10, thickness 128t2 is less than about 2 nm, or height 130Ch is greater than about 22 nm, S/D isolation layer 128-2 may not be able to isolate S/D contact structure 130C from S/D structure 110B2. If the ratio is less than about 3, thickness 128t2 is greater than about 8 nm, or height 130Ch is less than about 6 nm, S/D contact structure 130C may have worse electrical connection to S/D structure 110C and/or metal via 140C.

In some embodiments, as shown in FIG. 4, metal vias 140 and metal line 150 can connect S/D contact structure 130C to S/D contact structure 130B over gate structures 112. In some embodiments, metal vias 140 can include metal vias 140B and 140C. In some embodiments, metal vias 140 and metal line 150 can include any suitable conductive materials, such as tungsten, copper, aluminum, cobalt, titanium, ruthenium, titanium nitride, tantalum nitride, and other suitable conductive materials. Metal via 140C can be in contact with S/D contact structure 130C and metal via 140B can be in contact with S/D contact structure 130B. Metal line 150 can be in contact with metal vias 140B and 140C. With S/D isolation layer 128-2 isolating S/D contact structure 130C from S/D structures 110B2, S/D structures 110B1 and 110C at different sides of gate structures 112 for adjacent transistors 102B and 102C can be electrically connected through S/D contact structure 130B, metal via 140B, metal line 150, metal via 140C, and S/D contact structure 130C without additional metal interconnects. As a result, cell height of semiconductor device 100 can be reduced with fewer metal interconnects and the chip area of semiconductor device 100 can be reduced by about 2% to about 6%.

In some embodiments, as shown in FIGS. 1B, 2C, and 2D, S/D contact structure 130F can include a first portion 130-1 on S/D structure 110E2 and a second portion 130-2 on dielectric structure 138. In some embodiments, first portion 130-1 can be in contact with a top surface of S/D structure 110E2. In some embodiments, second portion 130-2 can be in contact with a top surface of dielectric structure 138. In some embodiments, silicide layers 132 can be on S/D structure 110E2 and electrically connect S/D structure 110E2 to first portion 130-1 of S/D contact structure 130F. In some embodiments, as shown in FIG. 2C, top surfaces of gate structures 112 and S/D contact structure 130F can be coplanar. In some embodiments, as shown in FIG. 2D, top surfaces of first portion 130-1 and second portion 130-2 of S/D contact structure 130F can be coplanar. In some embodiments, as shown in FIG. 2D, first portion 130-1 can have a height 130h1 along a Z-axis ranging from about 8 nm to about 40 nm. In some embodiments, as shown in FIG. 2D, second portion 130-2 can have a height 130h2 along a Z-axis ranging from about 5 nm to about 30 nm. In some embodiments, a ratio of height 130h2 to height 130h1 can range from about 0.2 to about 0.8. If the ratio is less than about 0.2, resistance of S/D contact structure 130F may increase and device performance may decrease. If the ratio is greater than about 0.8, S/D contact structure 130F may get closer to adjacent S/D structure 110F, the dielectric breakdown between S/D contact structure 130F and S/D structure 11OF may get worse and the reliability of semiconductor device 100 my decrease. In some embodiments, as shown in FIG. 2D, a distance 130Fd between second portion 130-2 of S/D contact structure 130F and S/D structure 110F can be greater than about 10 nm to avoid TDDB and improve device reliability. In some embodiments, S/D contact structure 130F can have a width along an X-axis ranging from about 9 nm to about 20 nm. In some embodiments, S/D contact structure 130F can have a width along a Y-axis ranging from about 12 nm to about 100 nm.

In some embodiments, as shown in FIGS. 2C-2D, dielectric structure 138 can be disposed on S/D structure 110E2. In some embodiments, dielectric structure 138 can be in contact with the top surface of S/D structure 110E2, bottom surfaces of second portion 130-2 of S/D contact structure 130F, and sidewall surfaces of ESL 116 and first portion 130-1 of S/D contact structure 130F. In some embodiments, as shown in FIG. 2D, dielectric structure 138 can be above a top surface of ILD layer 118. In some embodiments, ESL 116 can be on sidewall surfaces of S/D structure 110E2 and dielectric structure 138. In some embodiments, second portion 130-2 of S/D contact structure 130F can be on a top surface of ESL 116. In some embodiments, dielectric structure 138 can be enclosed by S/D structures 110E2, ESL 116, and S/D contact structure 130F. In some embodiments, dielectric structure 138 can include a dielectric material, such as silicon oxide, silicon nitride, silicon oxycarbide, silicon carbonitride, silicon oxynitride, silicon oxynitricarbide, and a combination thereof.

In some embodiments, as shown in FIG. 2C, dielectric structure 138 can have a height 138h along a Z-axis ranging from about 5 nm to about 10 nm. In some embodiments, a ratio of height 138h to height 130h1 can range from about 0.2 to about 0.8. If height 138h is less than about 5 nm or the ratio is less than about 0.2, S/D contact structure 130F may get closer to adjacent S/D structure 110F, the dielectric breakdown between S/D contact structure 130F and S/D structure 11OF may get worse and the reliability of semiconductor device 100 my decrease. If height 138h is greater than about 10 nm or the ratio is greater than about 0.8, the resistance of S/D contact structure 130F may increase and the device performance may decrease. With dielectric structure 138 between S/D structure 110E2 and second portion 130-2 of S/D contact structure 130F, distance 130Fd between S/D contact structure 130F and adjacent S/D structure 110F can be increased. As a result, TDDB can be reduced and the reliability of semiconductor device 100 can be improved.

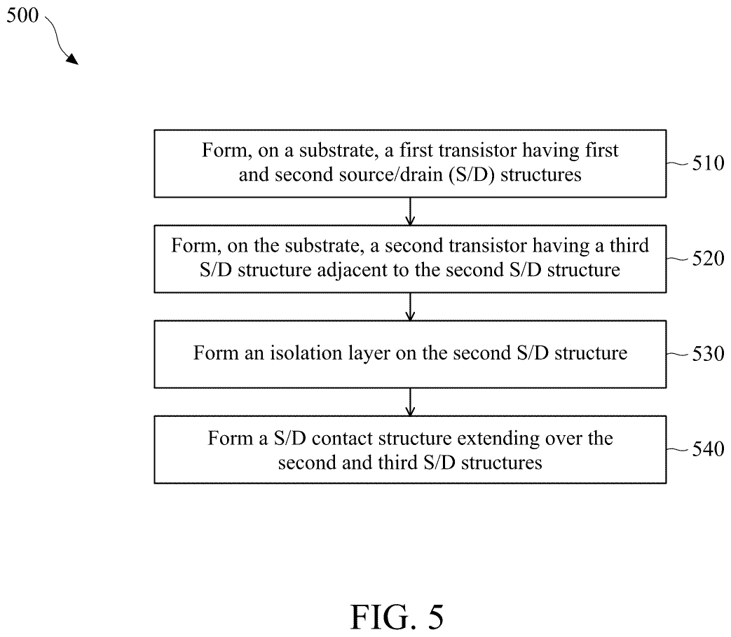

FIG. 5 is a flow diagram of a method 500 for fabricating semiconductor device 100 having a contact structure isolated from a source/drain structure, in accordance with some embodiments. Method 500 may not be limited to nanostructure transistor devices and can be applicable to other devices that would benefit from the contact structure isolated from the source/drain structure, i.e., the S/D contact flyer. Additional fabrication operations may be performed between various operations of method 500 and may be omitted merely for clarity and case of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

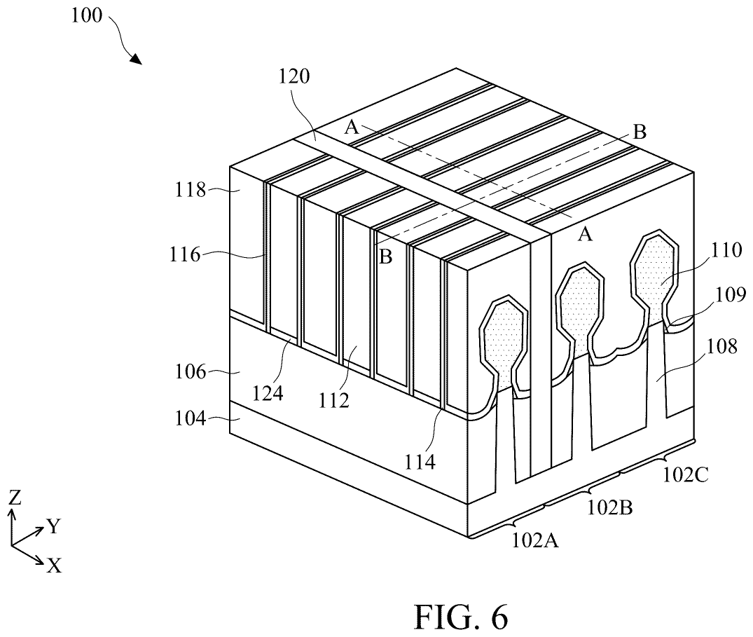

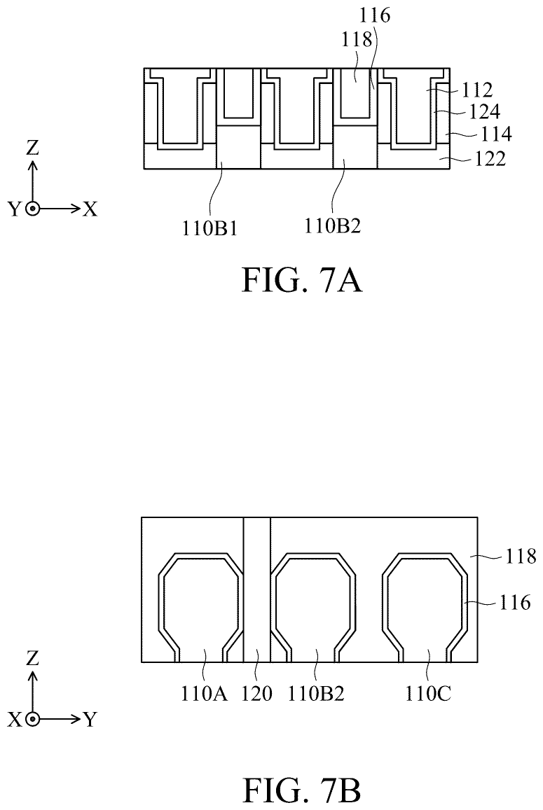

For illustrative purposes, the operations illustrated in FIG. 5 will be described with reference to the example fabrication process for fabricating semiconductor device 100 as illustrated in FIGS. 6-18. FIGS. 6-18 illustrate isometric and cross-sectional views of semiconductor device 100 having a contact structure isolated from a source/drain structure at various stages of its fabrication, in accordance with some embodiments. FIGS. 7A, 8A, 9A, 10A, 11A, 12A, and 13A illustrate partial cross-sectional views of semiconductor device 100 along line A-A as shown in FIG. 6 at various stages of its fabrication, in accordance with some embodiments. FIGS. 7B, 8B, 9B, 10B, 11B, 12B, and 13B illustrate partial cross-sectional views of semiconductor device 100 along line B-B as shown in FIG. 6 at various stages of its fabrication, in accordance with some embodiments. Elements in FIGS. 6-18 with the same annotations as elements in FIGS. 1A-4 are described above.

In referring to FIG. 5, method 500 begins with operation 510 and the process of forming, on a substrate, a first transistor having first and second S/D structures. For example, as shown in FIGS. 6 and 7A-7B, transistor 102B can be formed on substrate 104. Transistor 102B can include S/D structures 110B1 and 110B2. FIG. 6 illustrates an isometric view of semiconductor device 100 having transistor 102B, in accordance with some embodiments. FIG. 7A illustrates a partial cross-sectional view of semiconductor device 100 along line A-A as shown in FIG. 6, in accordance with some embodiments. FIG. 7B illustrates a partial cross-sectional view of semiconductor device 100 along line B-B as shown in FIG. 6, in accordance with some embodiments. In some embodiments, transistor 102B can include nanostructures 122 epitaxially grown on substrate 104. In some embodiments, nanostructures 122 can be in the form of nanosheets, nanowires, or nano-ribbons. In some embodiments, nanostructures 122 can include semiconductor materials similar to or different from substrate 104. In some embodiments, gate dielectric layer 124 and gate structures 112 can be formed on nanostructures 122. In some embodiments, ESL 116 and ILD layer 118 can be formed on S/D structures 110B1 and 110B2 on opposite sides of gate structures 112. In some embodiments, gate spacers 114 can be formed on sidewalls of gate structures 112 to isolate gate structures 112 from S/D structures 110 and subsequently formed S/D contact structures 130.

Referring to FIG. 5, method 500 continues with operation 520 and the process of forming, on the substrate, a second transistor having a third S/D structure adjacent to the second S/D structure. For example, as shown in FIGS. 6 and 7A-7B, transistor 102C can be formed on substrate 104. Transistor 102C can include S/D structure 110C adjacent to S/D structure 110B2. In some embodiments, transistor 102C can further include nanostructures 122, gate dielectric layer 124, gate structures 112, ESL 116, ILD layer 118, and gate spacers 114 as described for transistor 102B. In some embodiments, nanostructure transistors 102B and 102C can be both NFETs or PFETs. In some embodiments, either of nanostructure transistors 110B and 110C can be an NFET or a PFET. In some embodiments, gate isolation structure 120 can be formed on substrate 104 to isolate gate structures 112 of different transistors. For example, as shown in FIGS. 6 and 7B, gate isolation structures 120 can isolate gate structures 112 of transistor 102A from gate structures 112 of transistors 102B and 102C. The formation of gate isolation structure 120 can include an etching process to form an opening between transistors 102A and 102B and a dielectric material deposition process followed by a chemical mechanical planarization (CMP) process to planarize top surfaces of transistors 102A-102C.

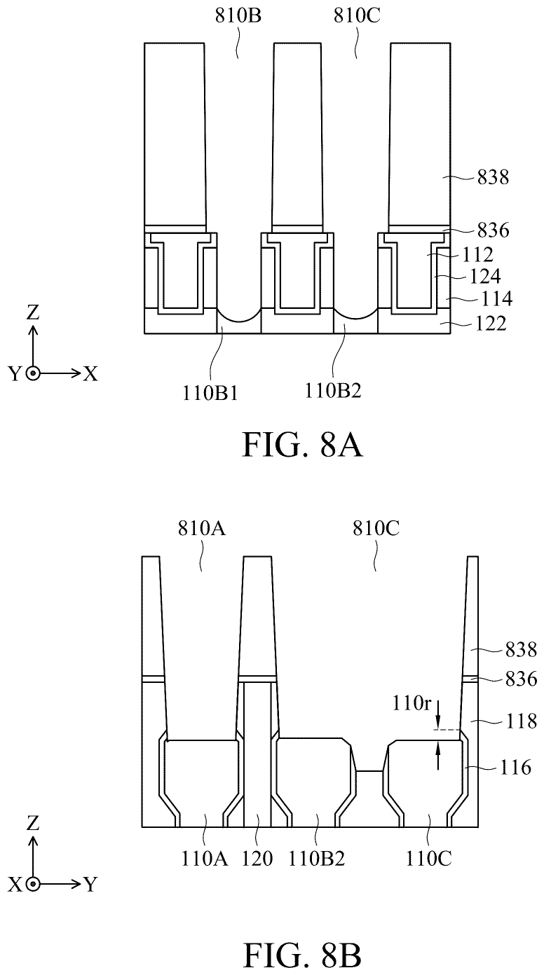

Referring to FIG. 5, in operation 530, an isolation layer can be formed on the second S/D structure. For example, as shown in FIGS. 8A-12B, dielectric layer 128 can be formed on S/D structure 110B2. In some embodiments, dielectric layer 128 can include a first portion 128-1 on sidewalls of openings 810A-810C and a second portion 128-2 on S/D structure 110B2. In some embodiments, the formation of dielectric layer 128 can include the formation of openings on S/D structures 110, blanket deposition of a dielectric material in the openings, and selective removal of the dielectric material from top surfaces of S/D structures 110.

In some embodiments, as shown in FIGS. 8A and 8B, ESL 836 and ILD layer 838 can be blanket deposited on gate structures 112 and ILD layer 118. A patterning process and an etching process can remove a portion of ILD layer 838, ESL 836, and ILD layer 118 to form openings 810A, 810B, and 810C. In some embodiments, openings 810A, 810B, and 810C can expose and partially recessed S/D structures 110. In some embodiments, S/D structures 110 can be etched by recess 110r ranging from about 2 nm to about 10 nm to reduce contact resistance of subsequently formed S/D contact structures 130.

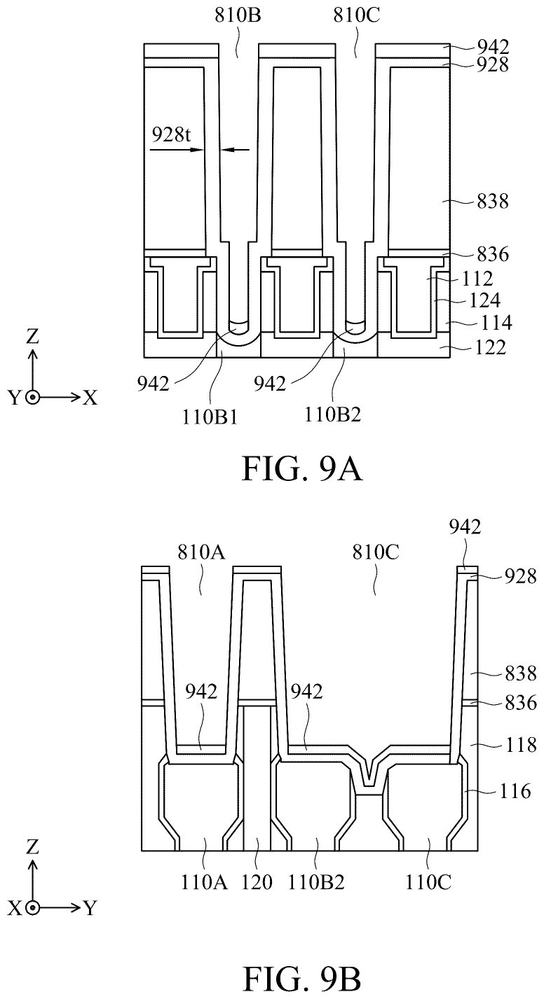

The formation of openings 810A, 810B, and 810C can be followed by the blanket deposition of a dielectric material in openings 810A, 810B, and 810C. For example, as shown in FIGS. 9A and 9B, a layer of dielectric material 928 can be blanket deposited in openings 810A, 810B, and 810C and on ILD layer 838. In some embodiments, dielectric material 928 can include silicon oxycarbide, silicon carbonitride, silicon oxynitride, silicon oxynitricarbide, or a combination thereof. In some embodiments, the layer of dielectric material 928 can have a thickness 928t ranging from about 2 nm to about 8 nm. In some embodiments, a hard mask layer 942 can be blanket deposited on the layer of dielectric material 928, as shown in FIGS. 9A and 9B. In some embodiments, hard mask layer 942 can be deposited by physical vapor deposition (PVD) or other suitable deposition method to maintain the width of openings 810A, 810B, and 810C. In some embodiments, hard mask layer 942 can be deposited at the bottoms of openings 810A, 810B, and 810C but not the sidewalls of openings 810A, 810B, and 810C.

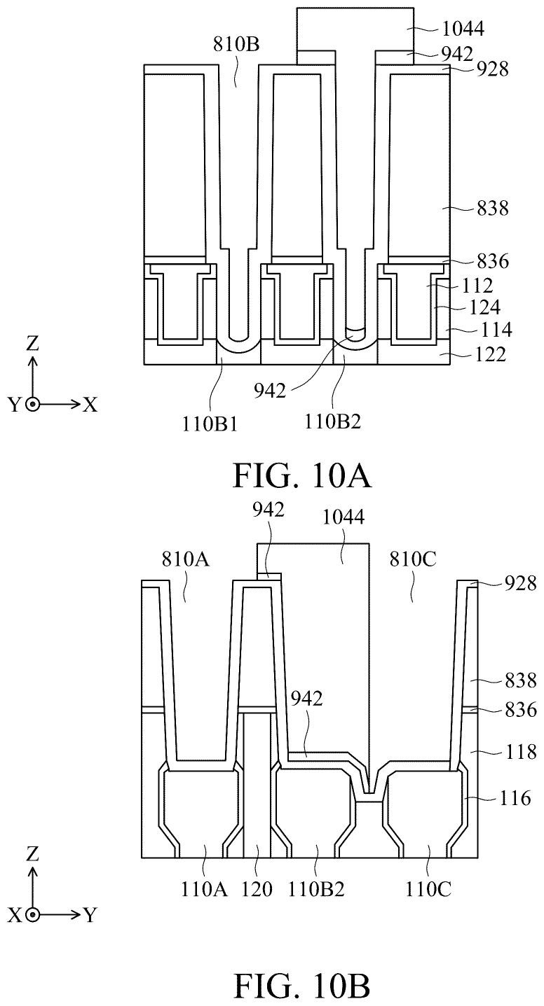

In some embodiments, as shown in FIGS. 10A and 10B, hard mask layer 942 can be patterned to selectively remove a portion of the layer of dielectric material 928. Photoresist 1044 can be blanket deposited on hard mask layer 942 and can be patterned to cover hard mask layer 942 over S/D structure 110B2. Hard mask layer 942 not covered by photoresist 1044 can be removed by a wet etching process. In some embodiments, hard mask layer 942 can be optionally trimmed before the deposition of photoresist 1044.

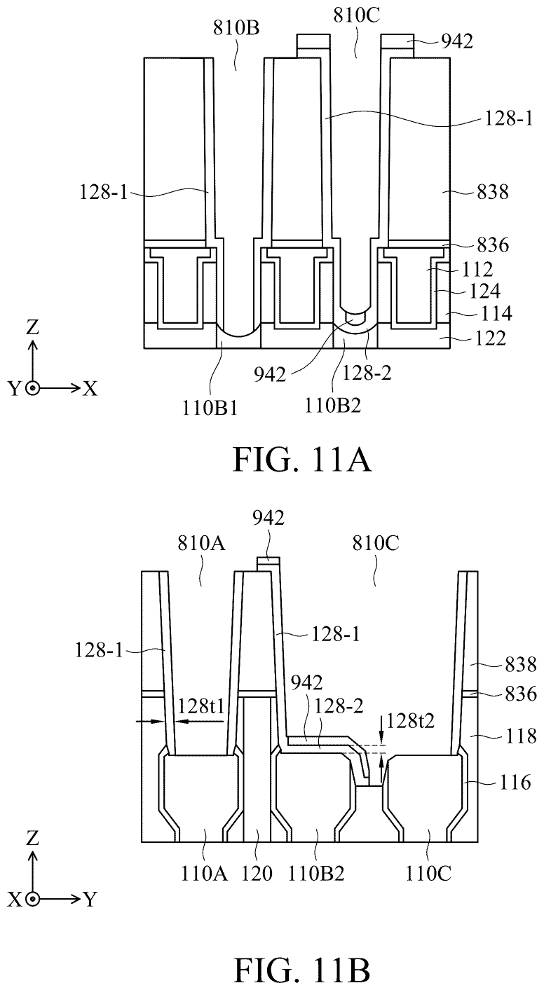

The removal of hard mask layer 942 not covered by photoresist 1044 can be followed by the selective removal of the layer of dielectric material 928. For example, as shown in FIGS. 11A and 11B, photoresist 1044 can be removed and hard mask layer 942 can protect the layer of dielectric material 928 on S/D structure 110B2 and around opening 810C. In some embodiments, an anisotropic etching process can etch the layer of dielectric material 928 outside hard mask layer 942 and form S/D contact spacers 128-1 and S/D isolation layer 128-2. In some embodiments, the anisotropic etching process can remove dielectric material 928 from top surfaces of ILD layer 838 and S/D structures 110A, 110B1, and 110C. In some embodiments, the anisotropic etching process can trim dielectric material 928 on sidewalls of openings 810A, 810B, and 810C to form S/D contact spacers 128-1. In some embodiments, S/D contact spacers 128-1 can have a thickness 128tl ranging from about 2 nm to about 5 nm. In some embodiments, hard mask layer 942 can protect dielectric material 928 on S/D structure 110B2 during the anisotropic etching process and form S/D isolation layer 128-2 on S/D structure 110B2. In some embodiments, S/D isolation layer 128-2 can be conformally formed on top and sidewall surfaces of S/D structure 110B2. In some embodiments, S/D isolation layer 128-2 can have a thickness 128t2 ranging from about 2 nm to about 8 nm. If thickness 128t2 is less than about 2 nm, S/D isolation layer 128-2 may not be able to isolate subsequently-formed S/D contact structure 130C from S/D structure 110B2. If thickness 128t2 is greater than about 8 nm, subsequently-formed S/D contact structure 130C may have worse electrical connection to S/D structure 110C and/or metal via 140C.

Referring to FIG. 5, in operation 540, a S/D contact structure is formed extending over the second and third S/D structures. For example, as shown in FIGS. 12A-12B, 13A-13B, and 2A-2B, S/D contact structure 130C can be formed extending over S/D structures 110B2 and 110C. In some embodiments, as shown in FIGS. 2A-2B, S/D contact structure 130C can be electrically connected to S/D structure 110C. In some embodiments, S/D contact structure 130C can be isolated from S/D structure 110B2 by S/D isolation layer 128-2. In some embodiments, as shown in FIGS. 2A-2B, 12A-12B, and 13A-13B, the formation of S/D contact structure 130C can include the formation of silicide layers 132A-132C, the formation of metal contact 134, and a CMP process.

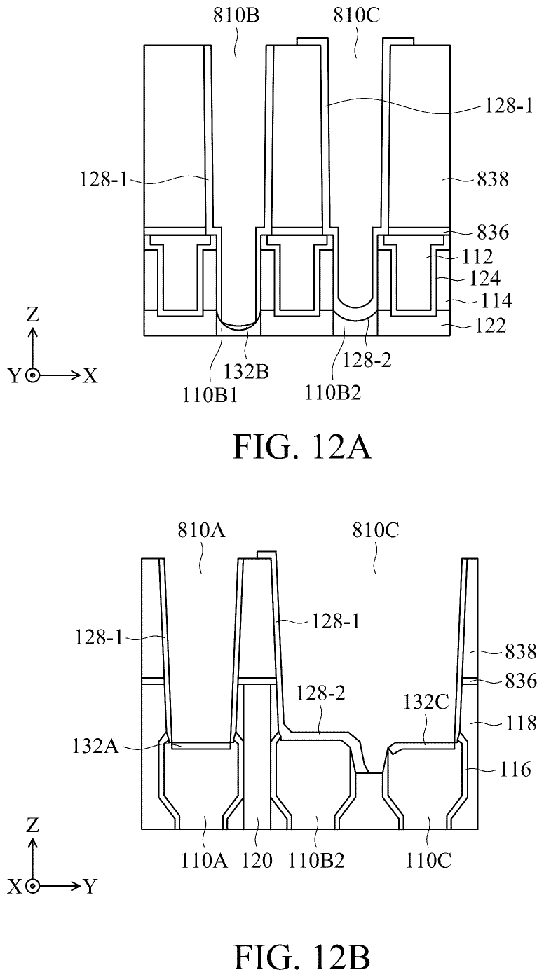

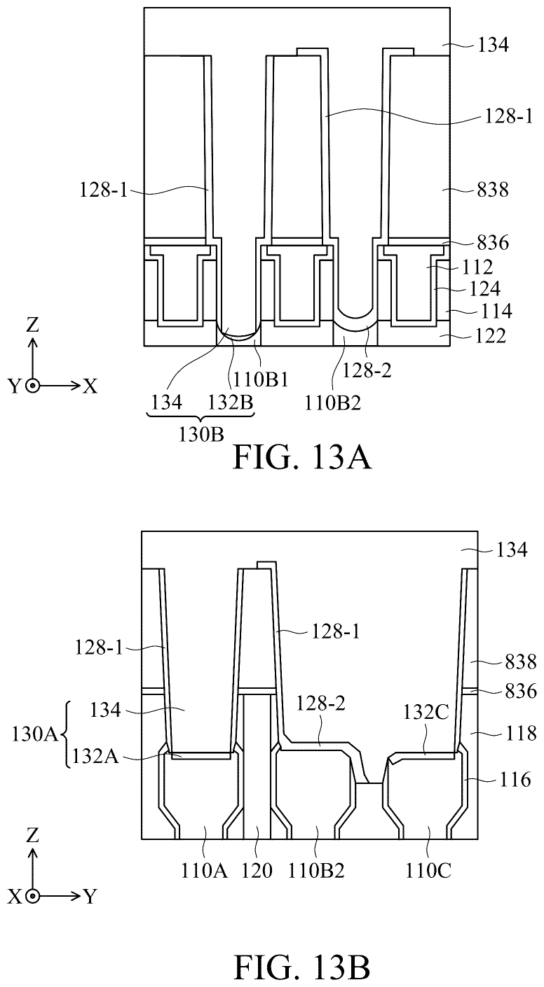

In some embodiments, as shown in FIGS. 12A and 12B, silicide layers 132A, 132B, and 132C can be formed on S/D structures 110A, 110B1, and 110C, respectively. In some embodiments, prior to the formation of silicide layers 132A-132C, hard mask layer 942 can be removed from S/D isolation layer 128-2. With S/D isolation layer 128-2 on S/D structure 110B2, silicide layers 132 may not be formed on S/D structure 110B2. In some embodiments, as shown in FIGS. 13A and 13B, the formation of silicide layers 132A-132C can be followed by the formation of metal contact 134. In some embodiments, a conductive material can be blanket deposited in openings 810A-810C and ILD layer 838 to fill openings 810A-810C. In some embodiments, the conductive material can include tungsten, aluminum, cobalt, or other suitable conductive material. In some embodiments, the formation of metal contact 134 can be followed by a CMP process to planarize top surfaces of S/D contact structures 130, S/D contact spacers 128-1, gate structures 112, gate spacers 114, gate isolation structure 120, and ILD layer 118.

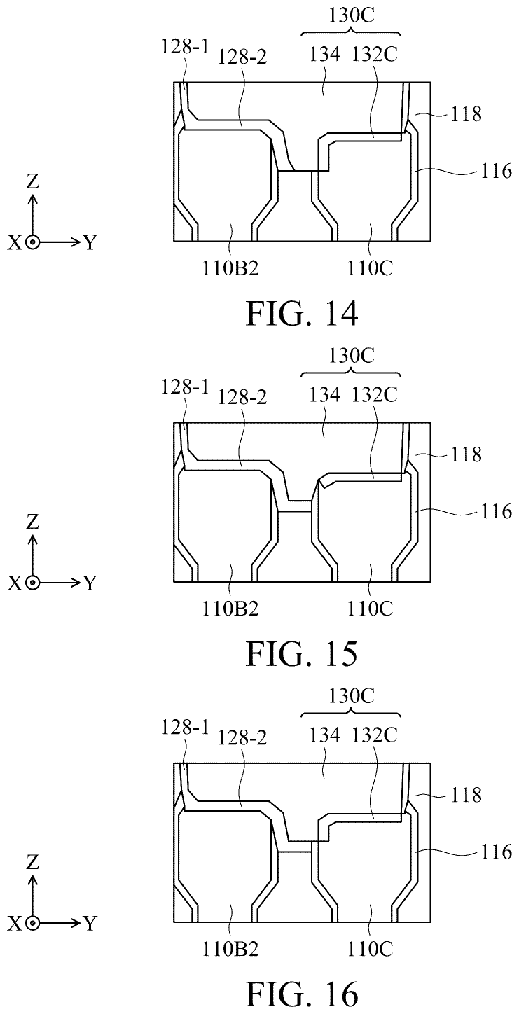

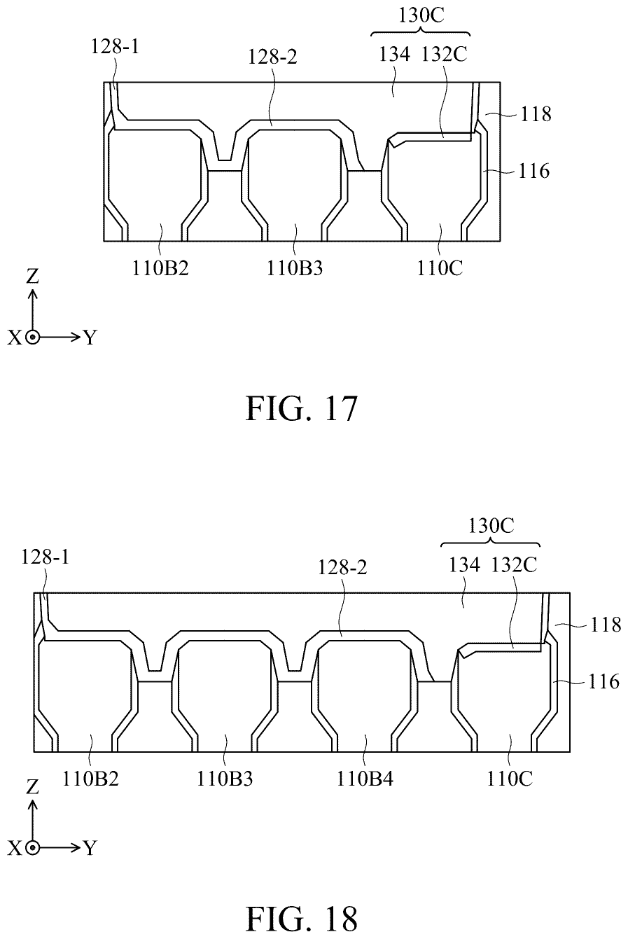

In some embodiments, as shown in FIG. 14, silicide layer 132C can cover top and sidewall surfaces of S/D structure 110C. In some embodiments, as shown in FIG. 15, silicide layer 132C can cover the top surface of S/D structure 110C and S/D isolation layer 128-2 can extend from top and sidewall surfaces of S/D structure 110B2 to sidewall surfaces of S/D structure 110C. S/D isolation layer 128-2 can be in contact with ESL 116 around S/D structure 110C. In some embodiments, as shown in FIG. 16, silicide layer 132C can cover the top and sidewall surfaces of S/D structure 110C and S/D isolation layer 128-2 can extend from the top and sidewall surfaces of S/D structure 110B2 to sidewall surfaces of S/D structure 110C. S/D isolation layer 128-2 can be in contact with ESL 116 around S/D structure 110C. In some embodiments, as shown in FIG. 17, S/D isolation layer 128-2 can extend over an additional S/D structure 110B3 between S/D structures 110B2 and 110C. In some embodiments, as shown in FIG. 18, S/D isolation layer 128-2 can extend over additional S/D structures 110B3 and 110B4 between S/D structures 110B2 and 110C. In some embodiments, S/D isolation layer 128-2 can extend over more S/D structures, such as about one S/D structures to about ten S/D structures.

In some embodiments, as shown in FIG. 4, the formation of S/D contact structures 130 can be followed by the formation of metal vias 140B and 140C, metal line 150, and additional ILD layers, which are not described in details for clarity. In some embodiments, with S/D contact structure 130C extending over S/D structures 110B2 and 110C while isolated from S/D structure 110B2 by S/D isolation layer 128-2, fewer interconnect structures are needed to electrically connect S/D structure 110B1 to S/D structure 110C. As a result, cell height of semiconductor device 100 can be reduced with fewer interconnect structures and the chip area of semiconductor device 100 can be reduced by about 2% to about 6%.

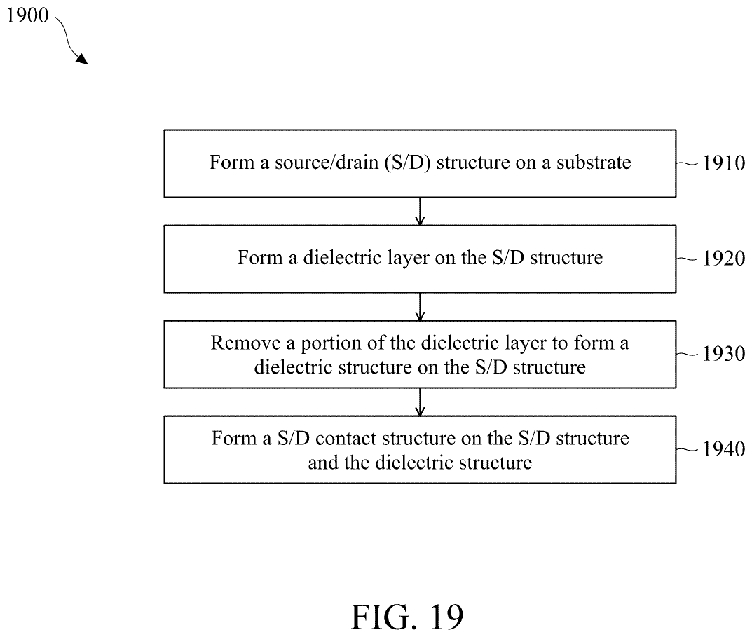

FIG. 19 is a flow diagram of a method 1900 for fabricating semiconductor device 100 having a dielectric structure between a source/drain structure and a contact structure, in accordance with some embodiments. Method 1900 may not be limited to nanostructure transistor devices and can be applicable to other devices that would benefit from the dielectric structure between the source/drain structure and the contact structure. Additional fabrication operations may be performed between various operations of method 1900 and may be omitted merely for clarity and case of description. Additional processes can be provided before, during, and/or after method 1900; one or more of these additional processes are briefly described herein. Moreover, not all operations may be needed to perform the disclosure provided herein. Additionally, some of the operations may be performed simultaneously or in a different order than shown in FIG. 19. In some embodiments, one or more other operations may be performed in addition to or in place of the presently-described operations.

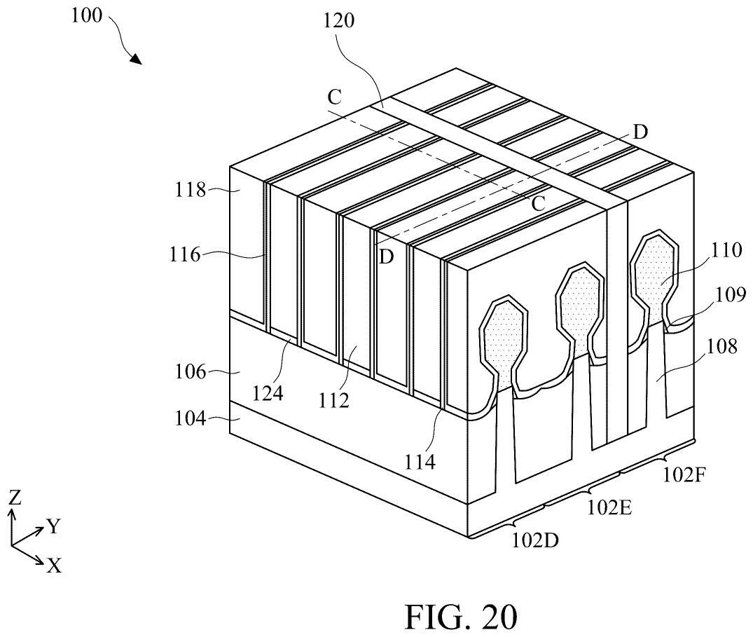

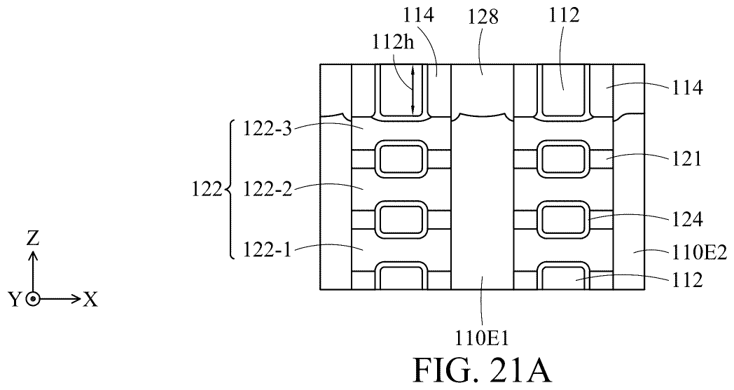

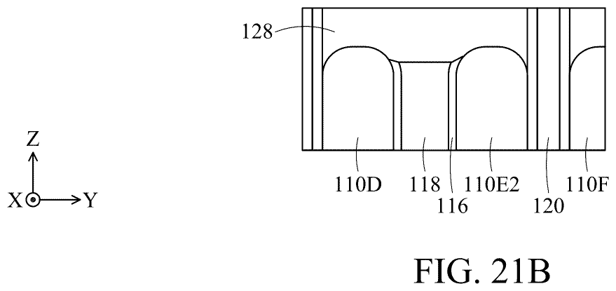

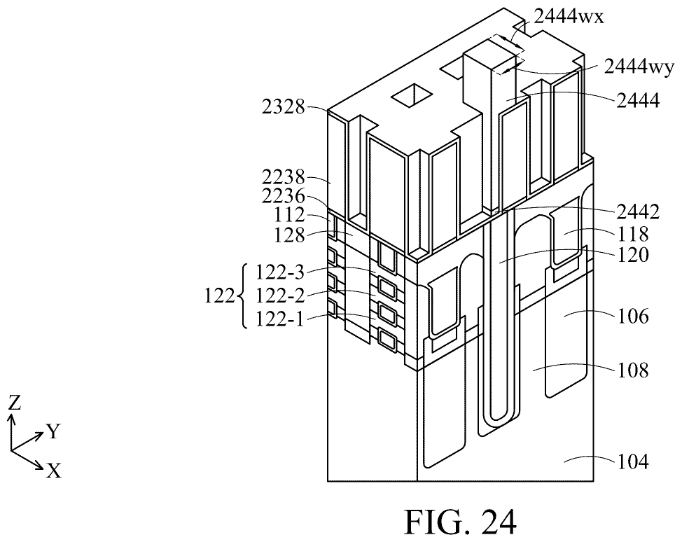

For illustrative purposes, the operations illustrated in FIG. 19 will be described with reference to the example fabrication process for fabricating semiconductor device 100 as illustrated in FIGS. 20-27B. FIGS. 20 and 24 illustrates isometric views of the second portion of semiconductor device 100 having a dielectric structure between a source/drain structure and a contact structure at various stages of its fabrication, in accordance with some embodiments. FIGS. 21A, 22A, 23A, 25A, 26A, and 27A illustrate partial cross-sectional views of semiconductor device 100 along line C-C as shown in FIG. 20 at various stages of its fabrication, in accordance with some embodiments. FIGS. 21B, 22B, 23B, 25B, 26B, and 27B illustrate partial cross-sectional views of semiconductor device 100 along line D-D as shown in FIG. 20 at various stages of its fabrication, in accordance with some embodiments. Elements in FIGS. 20-27B with the same annotations as elements in FIGS. 1A-2D are described above.

In referring to FIG. 19, method 1900 begins with operation 1910 and the process of forming a S/D structure on a substrate. For example, as shown in FIGS. 20 and 21A-21B, S/D structures 110D, 110E1, 110E2, and 110F of transistors 102D-102F can be formed on substrate 104. In some embodiments, nanostructure transistors 102D can be a PFET and nanostructure transistors 102E and 102F can be NFETs. In some embodiments, any of nanostructure transistors 110D-110F can be an NFET or a PFET. FIG. 20 illustrates an isometric view of semiconductor device 100 having S/D structures 110D, 110E1, 110E2, and 110F, in accordance with some embodiments. In some embodiments, transistor 102D-102F can include nanostructures 122 epitaxially grown on substrate 104. In some embodiments, nanostructures 122 can be in the form of nanosheets, nanowires, or nano-ribbons. In some embodiments, nanostructures 122 can include semiconductor materials similar to or different from substrate 104. In some embodiments, gate dielectric layer 124 and gate structures 112 can be formed on nanostructures 122. In some embodiments, ESL 116 and ILD layer 118 can be formed on S/D structures 110E1 and 110E2 on opposite sides of gate structures 112. In some embodiments, gate spacers 114 can be formed on sidewalls of gate structures 112 to isolate gate structures 112 from S/D structures 110 and subsequently-formed S/D contact structures 130.

Referring to FIG. 19, method 1900 continues with operation 1920 and the process of forming a dielectric layer on the S/D structure. For example, as shown in FIGS. 21A-21B, dielectric layer 128 can be formed on S/D structures 110 and ILD layer 118. In some embodiments, the formation of dielectric layer 128 can include removal of a portion of ILD layer 118 on S/D structures 110 and deposition of a dielectric material followed by a CMP process. The CMP process can planarize top surfaces of dielectric layer 128, gate structures 112, gate spacers 114, and gate isolation structure 120, as shown in FIGS. 21A and 21B. In some embodiments, the dielectric material can include silicon oxycarbide, silicon carbonitride, silicon oxynitride, silicon oxynitricarbide, or a combination thereof. In some embodiments, a thickness of dielectric layer 128 along a Z-axis can range from about 10 nm to about 40 nm.

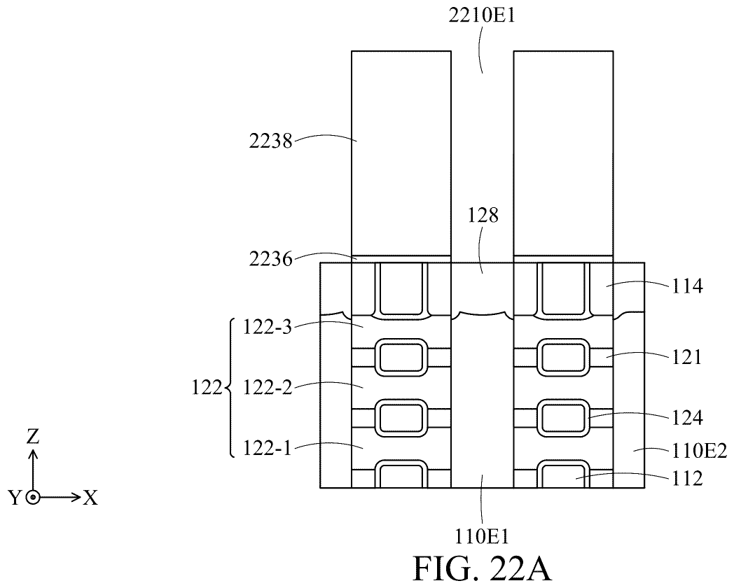

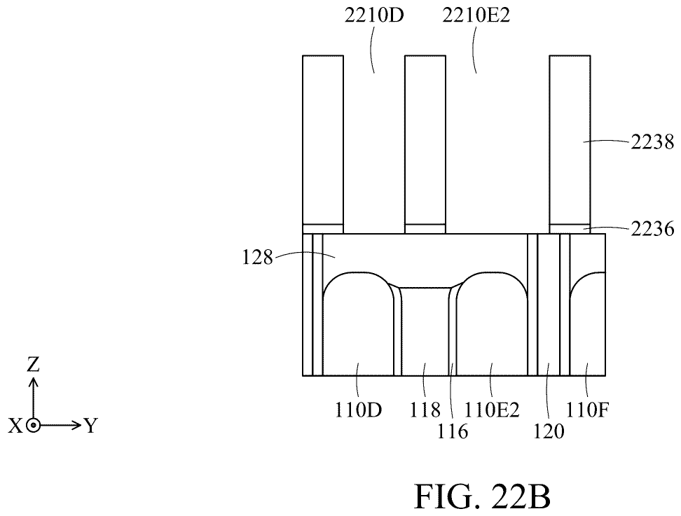

Referring to FIG. 19, in operation 1930, a portion of the dielectric layer is removed to form a dielectric structure on the S/D structure. For example, as shown in FIGS. 22A-26B, a portion of dielectric layer 128 can be removed to form dielectric structure 138 on S/D structure 110E2. In some embodiments, the formation of dielectric structure 138 can include deposition of ESL 2236 and ILD layer 2238, formation of openings over S/D structures 110, blanket deposition of a dielectric material in the openings, and selective removal of the dielectric material and dielectric layer 128 on S/D structures 110. The formation of dielectric structure 138 is described in detail below.

In some embodiments, as shown in FIGS. 22A and 22B, ESL 2236 and ILD layer 2238 can be blanket deposited on gate structures 112, ILD layer 118, and dielectric layer 128 after the formation of dielectric layer 128. A patterning process and an etching process can remove a portion of ILD layer 2238 and ESL 2236 to form openings 2210D, 2210E1, and 2210E2. In some embodiments, openings 2210D, 2210E1, and 2210E2 can be formed for subsequent formation of S/D contact structures 130D, 130E, and 130F. In some embodiments, openings 2210D, 2210E1, and 2210E2 can expose dielectric layer 128 above S/D structures 110.

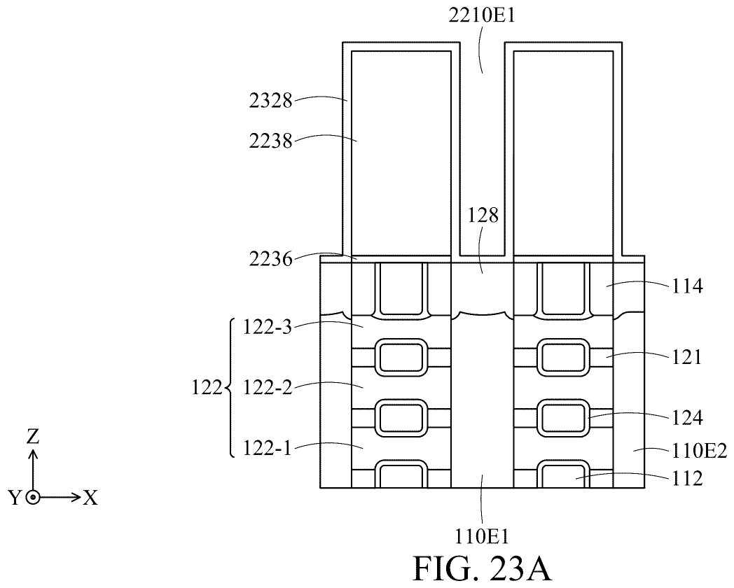

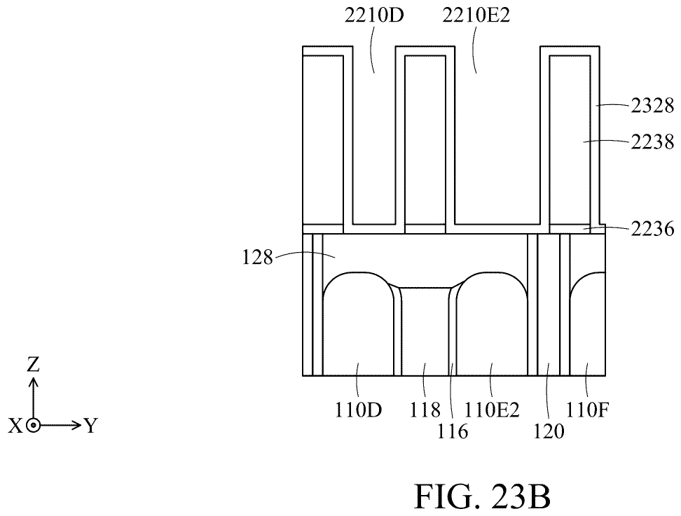

The formation of openings 2210D, 2210E1, and 2210E2 can be followed by the blanket deposition of a dielectric material in openings 2210D, 2210E1, and 2210E2. For example, as shown in FIGS. 23A and 23B, a layer of dielectric material 2328 can be blanket deposited in openings 2210D, 2210E1, and 2210E2 and on ILD layer 2238. In some embodiments, dielectric material 2328 can include silicon oxycarbide, silicon carbonitride, silicon oxynitride, silicon oxynitricarbide, or a combination thereof.

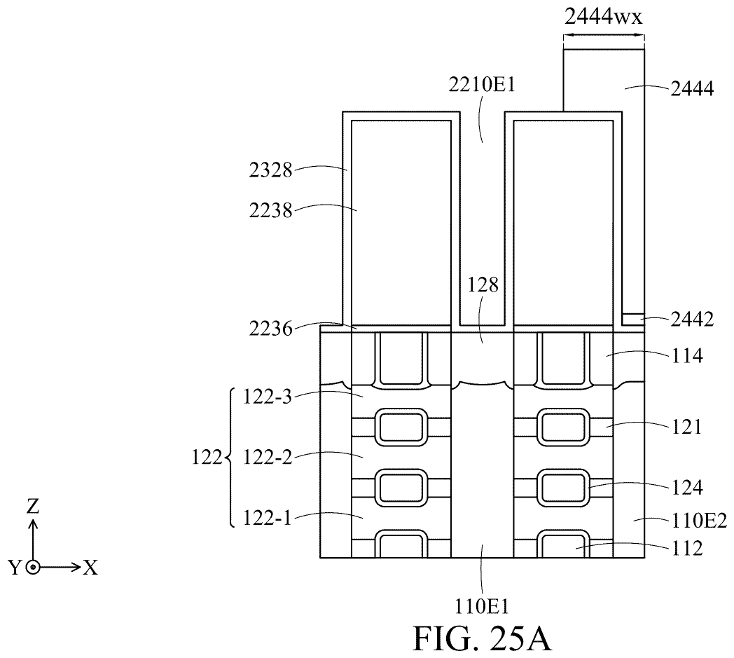

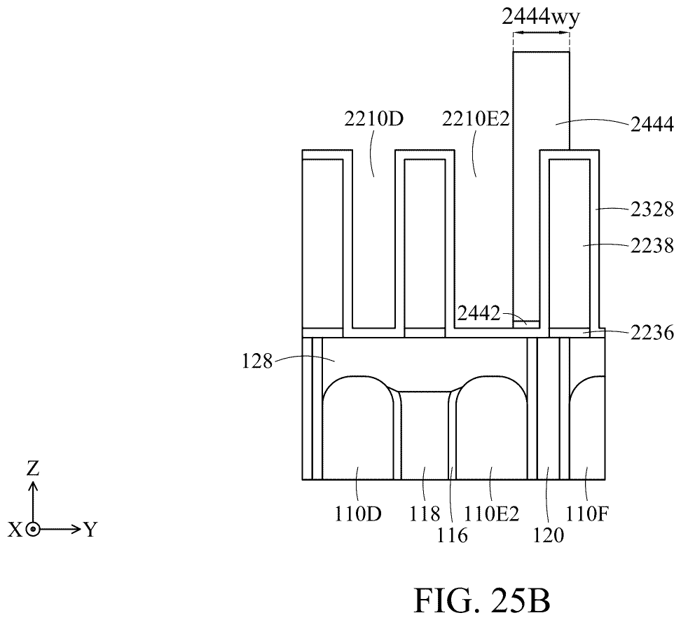

In some embodiments, hard mask layer 2442 and photoresist 2444 can be blanket deposited on the layer of dielectric material 2328 and patterned to cover a portion of S/D structure 110E2 and gate isolation structure 120, as shown in FIGS. 24 and 25A-25B. In some embodiments, hard mask layer 2442 can be deposited at the bottoms but not on the sidewalls of openings 2210D, 2210E1, and 2210E2 by physical vapor deposition (PVD) or other suitable deposition method. In some embodiments, one or two masks can be used in the patterning process to expose a portion of dielectric layer 128. In some embodiments, after the patterning process, photoresist 2444 can have a width 2444wx along an X-axis ranging from about 8 nm to about 20 nm. Photoresist 2444 can have a width 2444wy along a Y-axis ranging from about 20 nm to about 50 nm. In some embodiments, a size of patterned photoresist 2444 can control a size of dielectric structure 138 formed in subsequent processes. Width 2444wx can be about one gate pitch between adjacent gate structures. If width 2444wy is less than about 20 nm, dielectric structure 138 may not be formed. If width 2444wx is greater than about 50 nm, a size of subsequently-formed S/D contact structure 130F may decrease and the resistance of S/D contact structure 130F may increase.

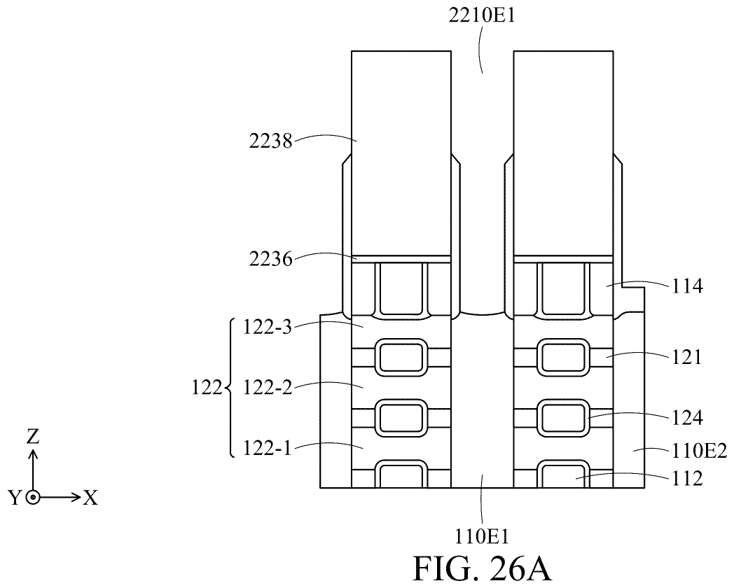

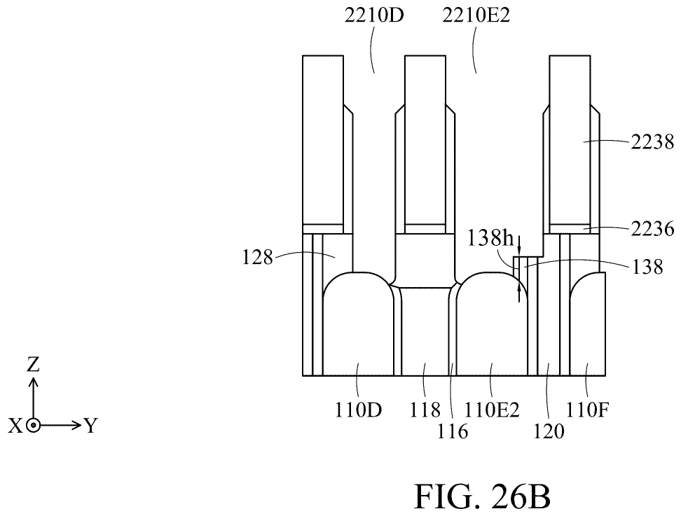

In some embodiments, as shown in FIGS. 26A and 26B, dielectric layer 128 not covered by photoresist 2444, hard mask layer 2442, ESL 2236, and ILD layer 2238 can be removed. In some embodiments, the exposed portion of dielectric layer 128 can be removed by an anisotropic etching process. In some embodiments, the anisotropic etching process can remove the layer of dielectric material 2328 and dielectric layer 128 from top surfaces of ILD layer 2238 and S/D structures 110. In some embodiments, the anisotropic etching process can trim a top portion of the layer of dielectric material 2328 on sidewalls of ILD layer 2238. In some embodiments, as shown in FIG. 26, the anisotropic etching process can remove a portion of dielectric layer 128, ESL 116, and gate isolation structure 120 to form dielectric structure 138. In some embodiments, after the anisotropic etching process, S/D structures 110 can be exposed and dielectric structure 138 can be formed on a top surface of a portion of S/D structure 110F2.

In some embodiments, dielectric structure 138 can have a height 138h along a Z-axis ranging from about 5 nm to about 10 nm. If height 138h is less than about 5 nm, subsequently-formed S/D contact structure 130F may get closer to adjacent S/D structure 110F, the dielectric breakdown between S/D contact structure 130F and S/D structure 11OF may get worse and the reliability of semiconductor device 100 my decrease. If height 138h is greater than about 10 nm, the resistance of subsequently-formed S/D contact structure 130F may increase and the device performance may decrease.

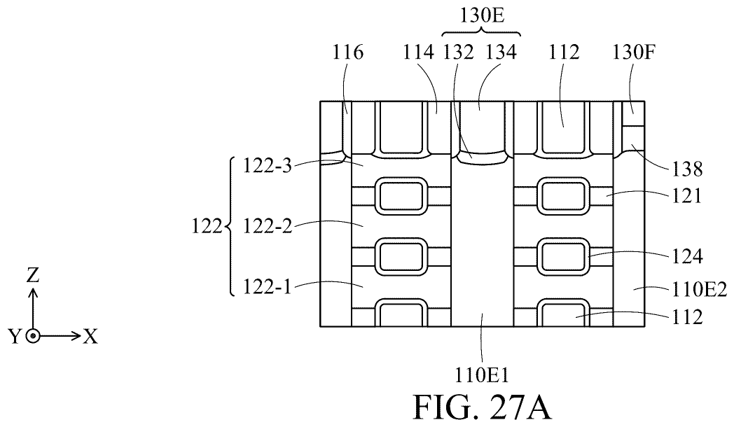

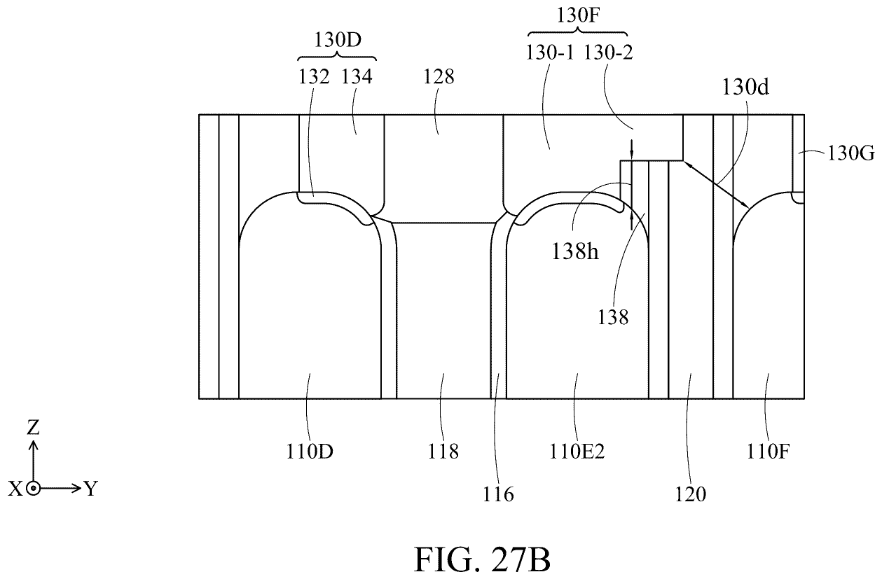

Referring to FIG. 19, in operation 1940, a S/D contact structure is formed on the S/D structure and the dielectric structure. For example, as shown in FIGS. 27A-B and 2C-2D, S/D contact structures 130 can be formed on S/D structure 110 and dielectric structure 138. In some embodiments, the formation of S/D contact structures 130 can include the formation of silicide layers 132, the formation of metal contact 134, and a CMP process. S/D contact structures 130 can be electronically connected to S/D structures 110. In some embodiments, S/D contact structure 130F can include first portion 130-1 on the top surface of S/D structure 130E2 and second portion 130-2 on the top surface of dielectric structure 138.

In some embodiments, as shown in FIGS. 27A-B and 2C-2D, silicide layers 132 can be formed on S/D structures 110D, 110E1, 110E2, and 110F. In some embodiments, after the formation of silicide layers 132, a conductive material can be blanket deposited on silicide layers 132, dielectric structure 138, and ILD layer 2238 to fill openings 2210D, 2210E2, and 2210E2. In some embodiments, the conductive material can include tungsten, aluminum, cobalt, or other suitable conductive material. In some embodiments, the formation of metal contact 134 can be followed by a CMP process to planarize top surfaces of S/D contact structures 130, gate structures 112, gate spacers 114, gate isolation structure 120, and ILD layer 118.

In some embodiments, as shown in FIGS. 27A-B and 2C-2D, dielectric structure 138 can in contact with the top surface of S/D structure 110E2 and second portion 130-2 of S/D contact structure 130F can be in contact with the top surface of dielectric structure 138. In some embodiments, dielectric structure 138 can be enclosed by S/D structures 110E2, ESL 116, and S/D contact structure 130F. In some embodiments, dielectric structure 138 can be in contact with the top surface of S/D structure 110E2, bottom surfaces of second portion 130-2 of S/D contact structure 130F, and sidewall surfaces of ESL 116 and first portion 130-1 of S/D contact structure 130F. In some embodiments, with dielectric structure 138 between S/D structure 110E2 and second portion 130-2 of S/D contact structure 130F, distance 130Fd between S/D contact structure 130F and adjacent S/D structure 110F can be increased. As a result, TDDB can be reduced and the reliability of semiconductor device 100 can be improved.

In some embodiments, S/D isolation layer 128-2 and dielectric structure 138 can be formed in the same process. In some embodiments, methods 500 and 1900 can be combined to for S/D isolation layer 128-2 and dielectric structure 138 in the same process. In some embodiments, photoresist 1044 and hard mask layer 942 can be patterned at the same time as photoresist 2444 and hard mask layer 2442 to simultaneously form S/D isolation layer 128-2 and dielectric structure 138. In some embodiments, with S/D isolation layer 128-2 and dielectric structure 138, semiconductor device 100 can have reduced metal interconnects and chip area as well as improved device reliability. In some embodiments, S/D isolation layer 128-2 and dielectric structure 138 can be formed in hybrid cells having different transistor sizes.

Some embodiments of the present disclosure provide example methods for forming S/D contact structure 130C isolated from S/D structure 110B2 in semiconductor device 100. In some embodiments, first and second transistors 102B and 102C can be formed on substrate 104. First transistor 102B can includes first and second S/D structures 110B1 and 110B2 and second transistor 102C can include third S/D structure 110C adjacent to second S/D structure 110B2. S/D isolation layer 128-2 can be formed on second S/D structure 110B2. S/D contact structure 130C can be formed over second and third S/D contact structures 110B2 and 110C. Third S/D structure 110C can be electrically connected to S/D contact structure 130C. S/D isolation layer 128-2 can isolate second S/D structure 110B2 from the S/D contact structure 130C. Accordingly, second S/D structure 110B1 and third S/D structure 110C can be electrically connected through S/D contact structure 130C, metal vias 140B and 140C, and metal line 150 without additional interconnects, such as metal lines M1. As a result, the cell height of semiconductor device 100 can be reduced with fewer metal interconnects and the chip area of semiconductor device 100 can be reduced.

Some embodiments of the present disclosure provide methods for forming dielectric structure 138 between S/D structure 110E2 and S/D contact structure 130F in semiconductor device 100. In some embodiments, S/D structure 110E2 can be formed on substrate 104. Dielectric structure 138 can be formed on the top surface of S/D structure 110E2. S/D contact structure 130F can be formed on S/D structure 110E2 and dielectric structure 138. Second portion 130-2 of S/D contact structure 130F can be in contact with the top surface of dielectric structure 138. With dielectric structure 138 between S/D structure 110E2 and second portion 130-2 of S/D contact structure 130F, distance 130Fd between S/D contact structure 130F and adjacent S/D structure 110F can be increased. As a result, TDDB can be reduced and the reliability of semiconductor device 100 can be improved.

In some embodiments, a semiconductor structure includes a source/drain (S/D) structure on a substrate, a dielectric structure on a top surface of the S/D structure, and a S/D contact structure on the S/D structure and the dielectric structure. A portion of the S/D contact structure is in contact with a top surface of the dielectric structure.

In some embodiments, a semiconductor device includes a gate structure on a substrate, first and second source/drain (S/D) structures on opposite sides of the gate structure, a dielectric structure on a top surface of the second S/D structure, and a S/D contact structure including a first portion and a second portion. The first portion is on the top surface of the second S/D structure and the second portion is in contact with a top surface of the dielectric structure.

In some embodiments, a method includes forming a source/drain (S/D) structure on a substrate, forming a dielectric layer on the S/D structure, removing a portion of the dielectric layer to form a dielectric structure on the S/D structure, and forming a S/D contact structure on the S/D structure and the dielectric structure. A portion of the S/D contact structure is in contact with the dielectric structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a source/drain (S/D) structure on a substrate;
a dielectric structure on a top surface of the S/D structure; and
a S/D contact structure on the S/D structure and the dielectric structure, wherein a portion of the S/D contact structure is in contact with a top surface of the dielectric structure.

2. The semiconductor structure of claim 1, wherein the S/D contact structure comprises a silicide layer in contact with the S/D structure.

3. The semiconductor structure of claim 1, further comprising an etch stop layer (ESL) on sidewall surfaces of the S/D structure, wherein the dielectric structure is between the ESL and the S/D contact structure.

4. The semiconductor structure of claim 3, wherein the portion of the S/D contact structure extends over the ESL.

5. The semiconductor structure of claim 1, further comprising:
a gate structure adjacent to the S/D structure and the S/D contact structure; and
a gate isolation structure extending through the gate structure, wherein the S/D contact structure extends into the gate isolation structure.

6. The semiconductor structure of claim 5, wherein top surfaces of the gate structure and the S/D contact structure are coplanar.

7. The semiconductor structure of claim 5, further comprising an additional S/D structure, wherein:
the S/D structure and the additional S/D structure are disposed on opposite sides of the gate isolation structure; and
a distance between the portion of the S/D contact structure to the additional S/D structure is greater than about 20 nm.

8. The semiconductor structure of claim 1, wherein a ratio of a height of the dielectric structure to a height of the S/D contact structure ranges from about 0.2 to about 0.8.

9. The semiconductor structure of claim 1, further comprising an interlayer dielectric layer adjacent to the S/D structure, wherein the dielectric structure is above a top surface of the interlayer dielectric layer, the interlayer dielectric layer comprises silicon oxide, and the dielectric structure comprises silicon nitride.

10. A semiconductor device, comprising:
a gate structure on a substrate;
first and second source/drain (S/D) structures on opposite sides of the gate structure;
a dielectric structure on a top surface of the second S/D structure; and
a S/D contact structure comprising a first portion and a second portion, wherein:
the first portion is on the top surface of the second S/D structure, and
the second portion is in contact with a top surface of the dielectric structure.

11. The semiconductor device of claim 10, wherein top surfaces of the gate structure and the first and second portions of the S/D contact structure are coplanar.

12. The semiconductor device of claim 10, wherein the S/D contact structure further comprises a silicide layer on the second S/D structure, and wherein the silicide layer electrically connects the second S/D structure to the first portion of the S/D contact structure.

13. The semiconductor device of claim 10, further comprising an etch stop layer (ESL) on sidewall surfaces of the second S/D structure and the dielectric structure, wherein the second portion of the S/D contact structure is on a top surface of the ESL.

14. The semiconductor device of claim 11, wherein the second S/D structure, the S/D contact structure, and the ESL encloses the dielectric structure.

15. The semiconductor device of claim 10, wherein a ratio of a height of the dielectric structure to a height of the first portion of the S/D contact structure ranges from about 0.2 to about 0.8.

16. A method, comprising:
forming a source/drain (S/D) structure on a substrate;
forming a dielectric layer on the S/D structure;
removing a portion of the dielectric layer to form a dielectric structure on the S/D structure; and
forming a S/D contact structure on the S/D structure and the dielectric structure, wherein a portion of the S/D contact structure is in contact with a top surface of the dielectric structure.

17. The method of claim 16, further comprising:
forming a gate structure adjacent to the S/D structure;
forming a gate isolation structure extending through the gate structure; and
planarizing top surfaces of the gate structure, the gate isolation structure, and the S/D contact structure.

18. The method of claim 16, wherein forming the S/D contact structure comprises:
forming a silicide layer on the S/D structure; and
forming a metal contact on the silicide layer.

19. The method of claim 16, wherein removing the portion of the dielectric layer comprises:
forming a hard mask layer on the dielectric layer;
forming a photoresist on the hard mask layer;
patterning the hard mask layer and the photoresist to expose a portion of the dielectric layer; and
etching the exposed portion of the dielectric layer.

20. The method of claim 19, wherein etching the exposed portion of the dielectric layer comprises performing an anisotropic etch on the dielectric layer.
